(19) United States
(12) Patent Application Publication
(10) Pub. No.: US 2025/0391636 A1
(43) Pub. Date: Dec. 25, 2025

(54) METHOD FOR PREPARING TEM SAMPLE

(71) Applicant: Shanghai Huali Microelectronics Corporation, Shanghai (CN)

(72) Inventors: Yi Xue, Shanghai (CN); Ming Li, Shanghai (CN)

(73) Assignee: Shanghai Huali Microelectronics Corporation, Shanghai (CN)

(21) Appl. No.: 18/810,421

(22) Filed: Aug. 20, 2024

(30) Foreign Application Priority Data
Jun. 21, 2024 (CN) 202410816298.7

(51) Int. Cl. H01J 37/305

(52) U.S. Cl. CPC H01J 37/3053; H01J 2237/31745; H01J 2237/31749

(57) ABSTRACT

The present disclosure discloses a method for preparing a TEM sample, including: fixing a chip sample on a sample stage of a FIB system, where the chip sample includes a semiconductor substrate, a target pattern layer, and a top pattern layer. The chip sample has a cuboid structure and includes a first side and a second side opposite each other and composed of a length and a height. A first protective layer is formed on one of the first side and the second side. First-time FIB cutting is performed to remove the top pattern layer. A top surface of the target pattern layer is etched to form a FIB mark pattern. A second protective layer is formed on the top surface of the target pattern layer. Based on localization of the FIB mark pattern, second-time FIB cutting is performed to form the TEM sample.

### CROSS-REFERENCES TO RELATED APPLICATIONS

This application claims priority to Chinese patent application No. CN202410816298.7, filed on Jun. 21, 2024, the disclosure of which is incorporated herein by reference in its entirety.

### TECHNICAL FIELD

The present disclosure relates to a method for manufacturing a semiconductor integrated circuit, and in particular to a method for preparing a TEM sample.

### BACKGROUND

As the integrated circuit (IC) process shrinks, improvements to the process may cause various problems in a chip. An effective means for failure analysis is cutting the chip using a focused ion beam (FIB) to prepare a sample with a thickness less than 100 nm and then observing the sample using a transmission electron microscope (TEM). Due to different process stations, it is sometimes required to perform fixed-point failure analysis of the front end of line on a chip of the back end of line.

In an existing positioning method, auxiliary localization of a target position on a lower layer is performed according to a layout of an upper layer structure, and then the target position on the lower layer is located by observing a change in a pattern of the upper layer structure during a TEM sample preparation process. However, the presence of different materials above a target result in different etch rates on the surface of the sample, affecting the flatness of a cross section, which is directly represented by ion beam pull marks in the shape of vertical strips generated on the cross section, i.e., a “curtain effect”. The “curtain effect” affects the thickness of the sample, making it difficult to expose some minor failure points, thereby affecting the failure analysis of the chip.

In addition, for some samples at the back end of metal, analysis for information of a metal gate is required. Since there are numerous metal lines with repeated structures above the metal gate, and sometimes one metal line contains multiple sets of metal gates, it is difficult to accurately locate the target position according to the layout of the upper layer structure alone, making it difficult to prepare a TEM sample. Therefore, there is an urgent need for a TEM sample preparation method, with which the target position in a lower layer structure can be accurately located.

### BRIEF SUMMARY

According to some embodiments in this application, a method for preparing a TEM sample is disclosed in the following steps:
fixing a chip sample on a sample stage of a FIB system, where the chip sample includes a semiconductor substrate, a target pattern layer formed above a top surface of the semiconductor substrate, and a top pattern layer located above the target pattern layer; the chip sample has a cuboid structure, a bottom surface of the chip sample is a bottom surface of the semiconductor substrate, a top surface of the chip sample is a top surface of the top pattern layer, and the chip sample includes a first side and a second side opposite each other and composed of a length and a height and a third side and a fourth side opposite each other and composed of a width and a height;
forming a first protective layer on one of the first side and the second side;
performing first-time FIB cutting on the chip sample using a FIB, to remove the top pattern layer and to expose a top surface of the target pattern layer, where a direction of the first-time FIB cutting points from a side on which the first protective layer is located to another side opposite the side;
etching the top surface of the target pattern layer using a FIB, to form a FIB mark pattern that defines a target position of the TEM sample;
forming a second protective layer on the top surface of the target pattern layer; and
based on localization of the FIB mark pattern, performing second-time FIB cutting on the chip sample using a FIB, to form the TEM sample, where a direction of the second-time FIB cutting points from the top surface of the target pattern layer to the bottom surface of the chip sample.

In some cases, the semiconductor substrate includes a silicon substrate.

In some cases, the target pattern layer includes a gate layer.

In some cases, the top pattern layer includes a metal interconnection layer.

In some cases, a gate structure in the gate layer includes a metal gate.

In some cases, a metal grid is provided on the sample stage, and the chip sample is fixed to the metal grid by means pf soldering.

In some cases, one of the third side and the fourth side of the chip sample is fixed to the metal grid.

In some cases, the width of the chip sample serves as a thickness, and the thickness of the chip sample is greater than 500 nm.

In some cases, the thickness of the TEM sample is less than 100 nm.

In some cases, the FIB system is a dual-beam system provided with a FIB and an electron beam, and there is a 52-degree angle between the FIB and the electron beam.

In some cases, the first protective layer is formed by means of an electron beam assisted deposition process.

In some cases, the second protective layer is formed by means of an electron beam assisted deposition process.

In some cases, the material of the second protective layer includes carbon.

In some cases, the sample stage has translation and rotation functions.

In some cases, the FIB mark pattern is composed of a plurality of trench strips and includes at least a first trench strip and a second trench strip parallel to each other, the first trench strip and the second trench strip respectively define two length edges of the TEM sample, and a distance between the first trench strip and the second trench strip defines the thickness of the TEM sample.

For the preparation of the TEM sample of the target pattern layer having the top pattern layer, in the present disclosure, the first-time FIB cutting is first performed to remove the top pattern layer and expose the target pattern layer, and then the FIB mark pattern is formed directly on the surface of the target pattern layer using a FIB for marking, where the FIB mark pattern is arranged according to the target position of the TEM sample, so that the FIB mark pattern may define the target position of the TEM sample. After that, the second-time cutting may be performed on the chip sample based on the localization of the FIB mark pattern, so as to implement accurate localization of the TEM sample.

In addition, since the first-time FIB cutting involves only the top pattern layer and does not involve a region below the target pattern layer, and the top pattern layer has been removed before the second-time cutting, no curtain effect is generated in the present disclosure.

Accordingly, with the present disclosure, the TEM sample of the target pattern layer having the top pattern layer can be accurately located without generating a curtain effect.

### BRIEF DESCRIPTION OF THE DRAWINGS

The present disclosure is further described in detail below with reference to the drawings and specific embodiments:

FIG. 1 is a flowchart of a method for preparing a TEM sample according to an embodiment of the present disclosure;

FIGS. 2-8E are schematic diagrams of structures of a chip sample in steps of the method for preparing a TEM sample according to an embodiment of the present disclosure;

FIGS. 9A-9F are pictures of the chip sample in the steps of the method for preparing a TEM sample according to an embodiment of the present disclosure;

FIG. 10A is a TEM low-magnification image of a TEM sample prepared by the method for preparing a TEM sample according to an embodiment of the present disclosure; and

FIG. 10B is a TEM high-magnification image of a TEM sample prepared by the method for preparing a TEM sample according to an embodiment of the present disclosure.

### DETAILED DESCRIPTION OF THE DISCLOSURE

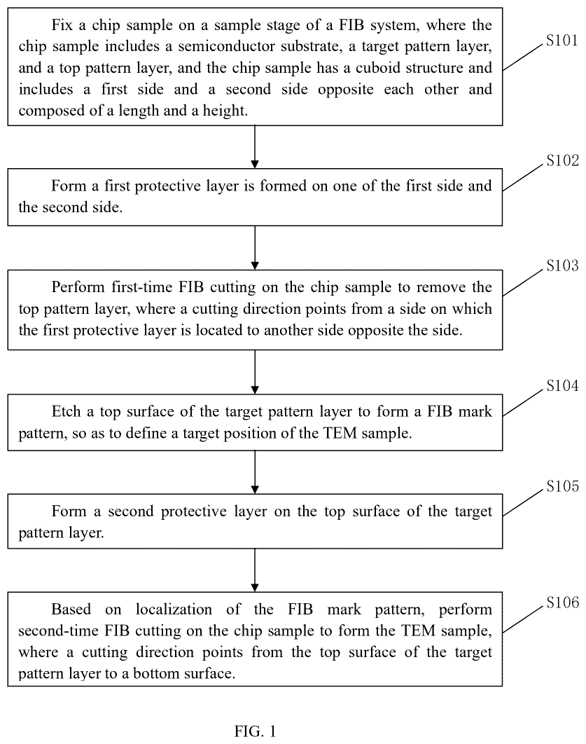

FIG. 1 is a flowchart of a method for preparing a TEM sample according to an embodiment of the present disclosure. FIGS. 2-8E are schematic diagrams of structures of a chip sample 101 in steps of the method for preparing a TEM sample according to an embodiment of the present disclosure. The method for preparing a TEM sample according to an embodiment of the present disclosure includes the following steps.

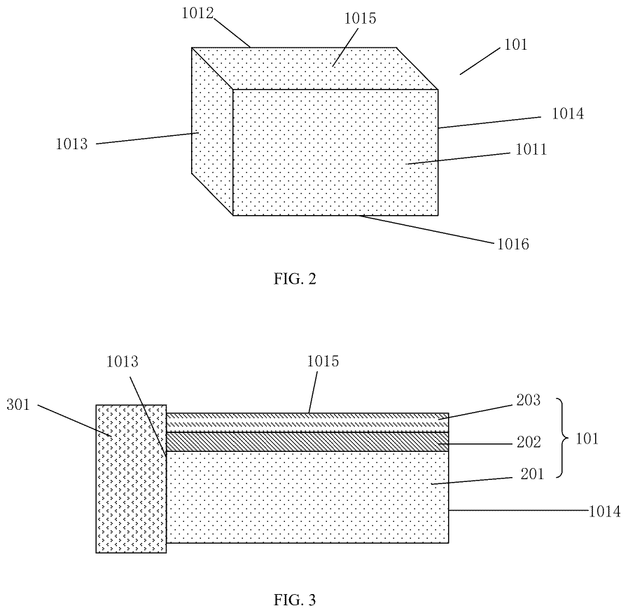

Step S101: Referring to FIG. 3, the chip sample 101 is fixed on a sample stage 301 of a FIB system.

The chip sample 101 includes a semiconductor substrate 201, a target pattern layer 202 formed above a top surface of the semiconductor substrate 201, and a top pattern layer 203 located above the target pattern layer 202.

FIG. 2 shows a three-dimensional structure of the chip sample 101. Referring to FIG. 2, the chip sample 101 has a cuboid structure, a bottom surface 1016 of the chip sample 101 is a bottom surface of the semiconductor substrate 201, a top surface 1015 of the chip sample 101 is a top surface of the top pattern layer 203, and the chip sample 101 includes a first side 1011 and a second side 1012 opposite each other and composed of a length and a height and a third side 1013 and a fourth side 1014 opposite each other and composed of a width and a height. In FIG. 2, the first side 1011 is a front side, the second side 1012 is a back side, the third side 1013 is a left side, and the fourth side 1014 is a right side.

In the embodiment of the present disclosure, the semiconductor substrate 201 includes a silicon substrate.

The target pattern layer 202 includes a gate layer. A gate structure in the gate layer includes a metal gate.

The top pattern layer 203 includes a metal interconnection layer. In an existing method, the position of TEM sample is usually located subsequently using a pattern of the metal interconnection layer. However, one metal line in the metal interconnection layer often includes multiple sets of the metal gates, and therefore accurate localization cannot be achieved. Moreover, in the existing method, during thinning of the TEM sample, i.e., the FIB cutting, the TEM sample is cut in a direction from the metal interconnection layer to the metal gate, thereby generating a curtain effect.

In the embodiment of the present disclosure, a metal grid is provided on the sample stage 301, and the chip sample 101 is fixed to the metal grid by means pf soldering.

One of the third side 1013 and the fourth side 1014 of the chip sample 101 is fixed to the metal grid.

The width of the chip sample 101 serves as a thickness, and the thickness of the chip sample 101 is greater than 500 nm. Typically, the chip sample 101 is obtained by performing cutting and thinning processes on a wafer composed of the semiconductor substrate 201.

The FIB system is a dual-beam system provided with a FIB and an electron beam, and there is a 52-degree angle between the FIB and the electron beam.

The sample stage 301 has translation and rotation functions. A focusing height may be adjusted using a motion function of the sample stage 301, e.g., adjusting an eucentric height. The direction of cutting the chip sample 101 with the FIB and a corresponding deposition surface for electron beam deposition may be adjusted using the rotation function of the sample stage 301. The sample stage 301 is usually arranged on a quick flip stage to implement a quick flip of the sample stage 301, e.g., a 90° flip, a 180° flip, etc. The sample stage 301 is also capable of a rotation of an angle of 52°, so as to facilitate a switch between FIB processing and electron beam processing.

FIG. 3 shows that the third side 1013 of the chip sample 101 is fixed to the metal grid. The third side 1013 of the chip sample 101 being fixed to the metal grid is illustrated as an example below. A front side observed in a direction toward the paper in FIG. 3 is the first side 1011. In FIG. 3, the metal grid is in a vertical state.

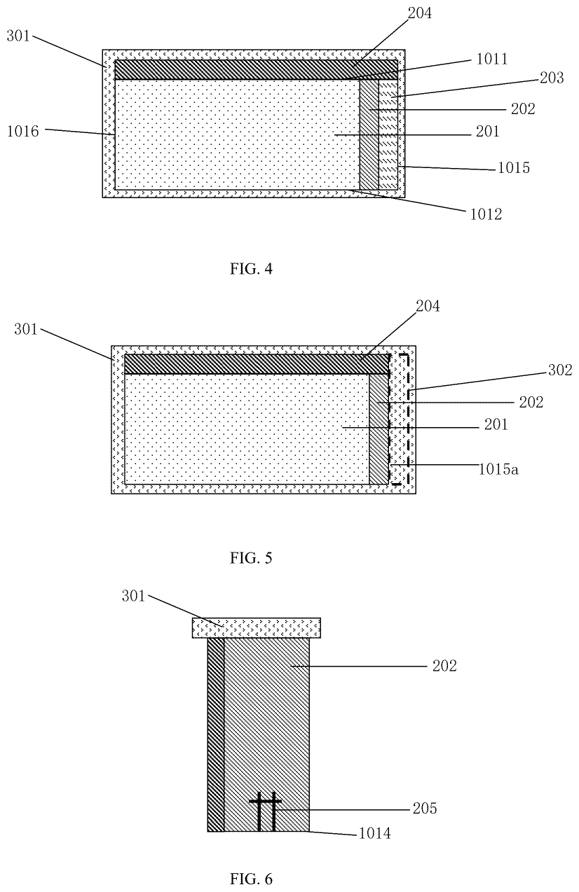

Step S102: Referring to FIG. 4, a first protective layer 204 is formed on one of the first side 1011 and the second side 1012. In FIG. 4, the first protective layer 204 is formed on the first side 1011. Since the first side 1011 and the second side 1012 are symmetrical, in other embodiments, the first protective layer 204 may also be formed on the second side 1012.

The metal grid in FIG. 4 is subjected to a flip of 90 degrees relative to that in FIG. 3, which can be achieved by means of the quick flip stage. A front side observed in the direction toward the paper in FIG. 4 is the fourth side 1014. The first side 1011 is at the top, and the second side 1012 is the bottom.

In the embodiment of the present disclosure, the first protective layer 204 is formed by means of an electron beam assisted deposition process. The material of the first protective layer 204 includes metal, such as platinum or tungsten.

Step S103: Referring to FIG. 5, first-time FIB cutting is performed on the chip sample 101 using a FIB, to remove the top pattern layer 203 and to expose a top surface of the target pattern layer 202, where a direction of the first-time FIB cutting points from a side on which the first protective layer 204 is located to another side opposite the side.

A front side observed in the direction toward the paper in FIG. 5 is also the fourth side 1014. The first side 1011 is at the top, and the second side 1012 is the bottom. However, compared with FIG. 4, in step S103, it is required to adjust the eucentric height and rotate the sample stage 301 by 52 degrees.

A region indicated by a dashed line 302 in FIG. 5 is a region removed by the first-time FIB cutting. A front side observed in the direction toward the paper in FIG. 5 is also the fourth side 1014. The top surface 1015 of the chip sample 101 is transferred downward to the top surface 1015a of the target pattern layer 202.

Step S104: Referring to FIG. 6, the top surface of the target pattern layer 202 is etched using a FIB, to form a FIB mark pattern 205 that defines a target position of the TEM sample.

The front side observed in the direction toward the paper in FIG. 6 is the top surface 1015a of the target pattern layer 202.

In the embodiment of the present disclosure, the FIB mark pattern 205 is composed of a plurality of trench strips and includes at least a first trench strip and a second trench strip parallel to each other, the first trench strip and the second trench strip respectively define two length edges of the TEM sample, and a distance between the first trench strip and the second trench strip defines the thickness of the TEM sample. In FIG. 6, the FIB mark pattern 205 further includes a third trench strip perpendicularly intersecting the first trench strip and the second trench strip.

In the embodiment of the present disclosure, the FIB mark pattern 205 is close to the fourth side 1014. In other embodiments, the FIB mark pattern 205 may also be located at another suitable position between the third side 1013 and the fourth side 1014, as long as the position of the TEM sample can be accurately defined.

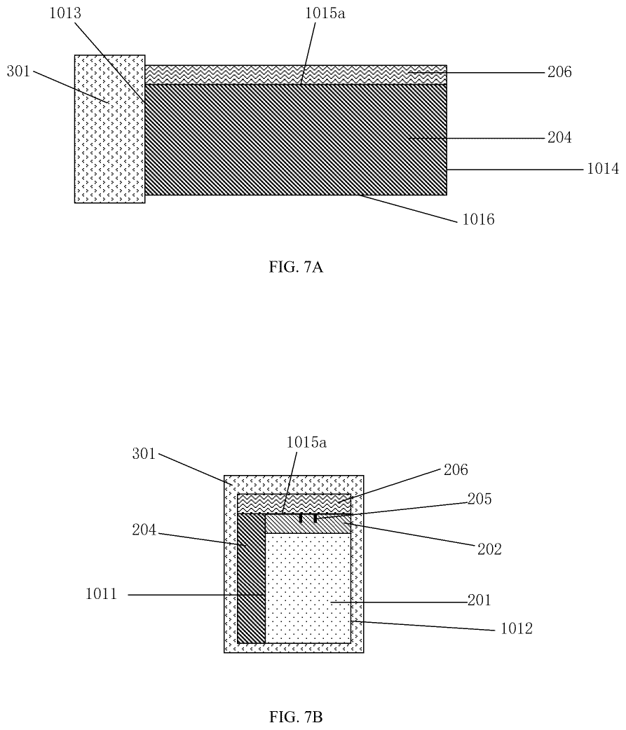

Step S105: Referring to FIG. 7A, a second protective layer 206 is formed on the top surface 1015a of the target pattern layer 202.

In the embodiment of the present disclosure, the second protective layer 206 is formed by means of an electron beam assisted deposition process.

The material of the second protective layer 206 includes carbon.

The front side observed in the direction toward the paper in FIG. 7 is a top surface of the first protective layer 204. A bottom surface of the first protective layer 204 is the first side 1011.

A structure in FIG. 7B is the same as that in FIG. 7A, except that they are observed in different directions. A front side observed in the direction toward the paper in FIG. 7B is the fourth side 1014. Since the FIB mark pattern 205 is close to the fourth side 1014, the FIB mark pattern 205 can be observed in FIG. 7B.

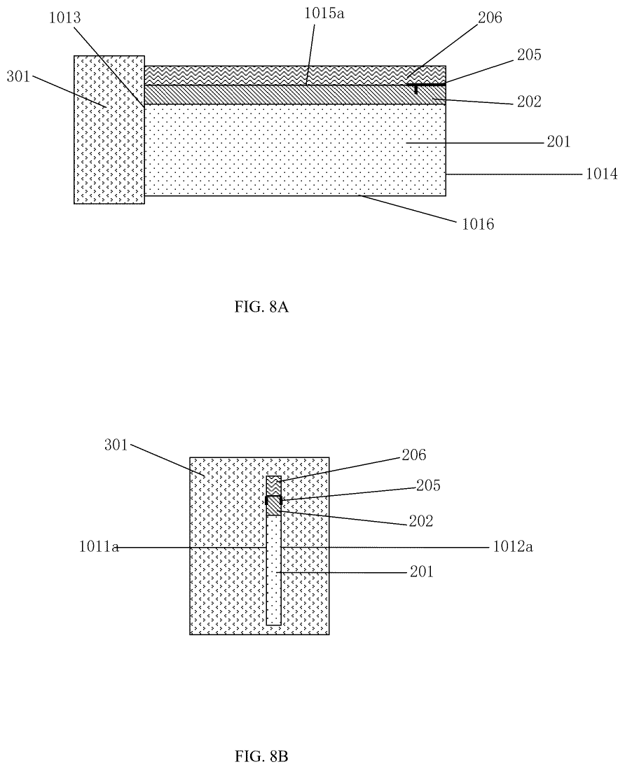

Step S106: Referring to FIG. 8A, based on localization of the FIB mark pattern 205, second-time FIB cutting is performed on the chip sample 101 using a FIB, to form the TEM sample, where a direction of the second-time FIB cutting points from the top surface of the target pattern layer 202 to the bottom surface 1016 of the chip sample 101.

An observation direction in FIG. 8A is the same as that in FIG. 7A, and the direction correspondingly points from the first side 1011 to the second side 1012. After the second-time FIB cutting, the first protective layer 204 is removed and a corresponding side of the semiconductor substrate 201 is exposed. Referring to FIG. 2, the first side 1011 gradually moves in a direction toward the second side 1012, and the corresponding cutting is stopped when it reaches the position defined by the FIB mark pattern 205, for example, a position corresponding to the first trench strip. Accordingly, the corresponding side of the semiconductor substrate 201 is exposed in FIG. 8A.

Similarly, in another direction corresponding to FIG. 8A, i.e., a direction pointing from the second side 1012 to the first side 1011, after the second-time FIB cutting, the second side 1012 gradually moves in a direction toward the first side 1011, and the corresponding cutting is stopped when it reaches the position defined by the FIB mark pattern 205, for example, a position corresponding to the second trench strip. Therefore, a region for the second-time FIB cutting actually includes two regions that, however, are cut in the same direction, where one region is cut after cutting of the other region is completed, or both regions are cut alternately.

A structure in FIG. 8B is the same as that in FIG. 8A, except that they are observed in different directions. An observation direction in FIG. 8B is the same as that in FIG. 7B That is, a front side observed in the direction toward the paper in FIG. 8B is the fourth side 1014. As can be seen from FIG. 8B, after the second-time FIB cutting, the first side 1011 moves to a side 1011a, and the second side 1012 moves to a side 1012a.

In FIG. 8B, a structure located between the side 1011a and the side 1012a is the TEM sample. As shown in FIG. 8A, the direction of the second-time FIB cutting is a direction from top to bottom in FIG. 8A, and it can be seen that the target pattern layer 202 no longer has the top pattern layer 203 at the top thereof, so that no curtain effect occurs. Moreover, the position of where the cutting is finally stopped is accurately located by the FIB mark pattern 205, so that the obtained position of the TEM sample is accurate, i.e. the TEM sample may accurately include a desired failure analysis region.

In some embodiments, the thickness of the TEM sample is less than 100 nm.

For the preparation of the TEM sample of the target pattern layer 202 having the top pattern layer, in the embodiment of the present disclosure, the first-time FIB cutting is first performed to remove the top pattern layer 203 and expose the target pattern layer 202, and then the FIB mark pattern 205 is formed directly on the surface of the target pattern layer 202 using a FIB for marking, where the FIB mark pattern 205 is arranged according to the target position of the TEM sample, so that the FIB mark pattern 205 may define the target position of the TEM sample. After that, the second-time cutting may be performed on the chip sample 101 based on the localization of the FIB mark pattern 205, so as to implement accurate localization of the TEM sample.

In addition, since the first-time FIB cutting involves only the top pattern layer 203 and does not involve a region below the target pattern layer 202, and the top pattern layer 203 has been removed before the second-time cutting, no curtain effect is generated in the present disclosure.

Accordingly, with the embodiment of the present disclosure, the TEM sample of the target pattern layer 202 having the top pattern layer can be accurately located without generating a curtain effect.

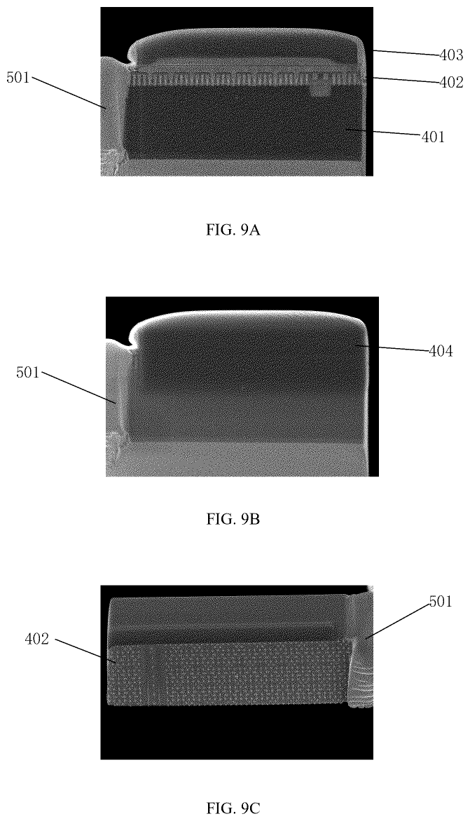

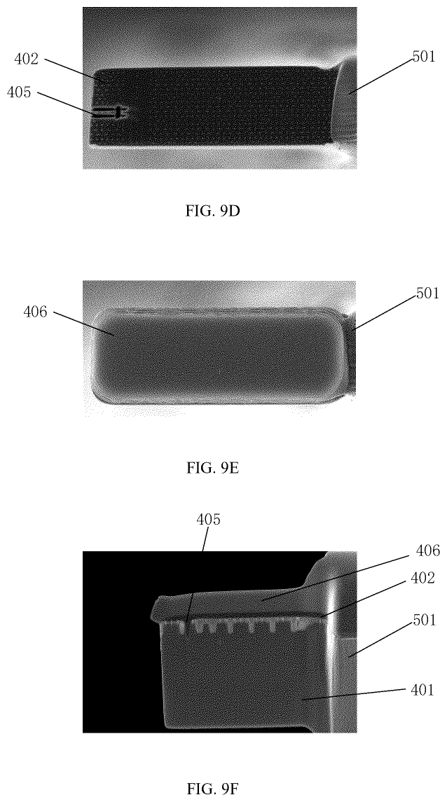

FIGS. 9A-9F are pictures of the chip sample in the steps of the method according to the embodiment of the present disclosure. In practical operation, there is a design for control of tilt and rotation angles of a sample stage 501, which is described separately below:

As shown in FIG. 9A, a chip is first grounded using a laser mark, and a sample target region, i.e., a chip sample, is soldered to a metal grid of the sample stage 501 using a nano manipulator. The chip sample in FIG. 9A sequentially includes a semiconductor substrate 401, a target pattern layer 402 formed above a top surface of the semiconductor substrate 401, and a top pattern layer 403 located above the target pattern layer 402. A metal grid is located on the sample stage 501.

At this time, the metal grid is in a vertical placement state.

Then, the quick flip stage is flipped by 90° so that the metal grid is placed horizontally.

Referring to FIG. 9B, a protective layer 404 is deposited above the cross section of the chip sample.

Referring to FIG. 9C, the eucentric height is configured, the sample stage 501 is rotated to an angle of 50°, i.e., tilted by 52°, and the chip sample is thinned to cut off a structure above the target pattern layer 402, i.e., the top pattern layer 403.

Referring to FIG. 9D, based on a layout map of the target pattern layer 402, a target location is located by using a FIB mark, i.e., forming a FIB mark pattern 405.

Then, the quick flip stage is flipped by 90° so that the metal grid is placed vertically.

Referring to FIG. 9E, a protective layer 406 is deposited above the target pattern layer 402, where the material of the protective layer 406 includes carbon, to implement a protection function in subsequent ion beam bombardment for cutting the sample.

Referring to FIG. 9F, the chip sample is thinned, and the desired TEM sample is obtained according to mark localization.

The embodiment of the present disclosure is applicable to a sample of a target structure having multiple layers of structures above it, where a structure above the target position may be removed, and then the target position is accurately located by means of a layout map of the target current layer. With the embodiment of the present disclosure, an impact of the ion beam pull marks on a TEM image of a target region may be minimized.

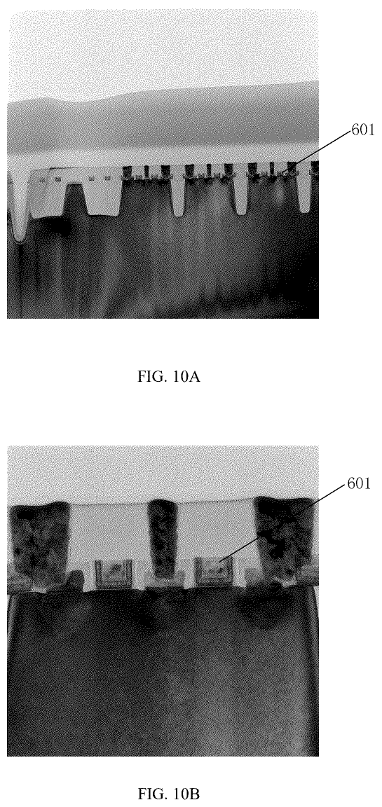

For a chip sample of the back end of metal that is the existing process station, analysis for a metal gate region of a SRAM structure is required. With the method of the embodiment of the present disclosure, the target position may be accurately located, and the impact of the ion beam pull marks on the TEM image analysis is alleviated. FIG. 10A is a TEM low-magnification image of the TEM sample prepared by the method for preparing a TEM sample according to the embodiment of the present disclosure, where an image of a metal grid 601 is clear and free of ion beam pull marks. FIG. 10B is a TEM high-magnification image of the TEM sample prepared by the method for preparing a TEM sample according to the embodiment of the present disclosure, where an image of the metal grid 601 is clear and free of ion beam pull marks.

The present disclosure is described in detail above through specific embodiments that, however, do not impose limitations to the present disclosure. Without departing from the principle of the present disclosure, a skilled in the art may also made many other deformations and improvements, which should also be considered as the scope of protection of the present disclosure.

What is claimed is:

1. A method for preparing a TEM sample, comprising the following steps:
fixing a chip sample on a sample stage of a FIB system, wherein the chip sample comprises a semiconductor substrate, a target pattern layer formed above a top surface of the semiconductor substrate, and a top pattern layer located above the target pattern layer; the chip sample has a cuboid structure, a bottom surface of the chip sample is a bottom surface of the semiconductor substrate, a top surface of the chip sample is a top surface of the top pattern layer, and the chip sample comprises a first side and a second side opposite each other and composed of a length and a height and a third side and a fourth side opposite each other and composed of a width and a height;
forming a first protective layer on one of the first side and the second side;
performing first-time FIB cutting on the chip sample using a FIB, to remove the top pattern layer and to expose a top surface of the target pattern layer, wherein a direction of the first-time FIB cutting points from a side on which the first protective layer is located to another side opposite the side;
etching the top surface of the target pattern layer using a FIB, to form a FIB mark pattern that defines a target position of the TEM sample;
forming a second protective layer on the top surface of the target pattern layer; and
based on localization of the FIB mark pattern, performing second-time FIB cutting on the chip sample using a FIB, to form the TEM sample, wherein a direction of the second-time FIB cutting points from the top surface of the target pattern layer to the bottom surface of the chip sample.

2. The method for preparing a TEM sample according to claim 1, wherein the semiconductor substrate comprises a silicon substrate.

3. The method for preparing a TEM sample according to claim 1, wherein the target pattern layer comprises a gate layer.

4. The method for preparing a TEM sample according to claim 3, wherein the top pattern layer comprises a metal interconnection layer.

5. The method for preparing a TEM sample according to claim 3, wherein a gate structure in the gate layer comprises a metal gate.

6. The method for preparing a TEM sample according to claim 1, wherein a metal grid is provided on the sample stage, and the chip sample is fixed to the metal grid by means pf soldering.

7. The method for preparing a TEM sample according to claim 6, wherein one of the third side and the fourth side of the chip sample is fixed to the metal grid.

8. The method for preparing a TEM sample according to claim 1, wherein the width of the chip sample serves as a thickness, and the thickness of the chip sample is greater than 500 nm.

9. The method for preparing a TEM sample according to claim 8, wherein the thickness of the TEM sample is less than 100 nm.

10. The method for preparing a TEM sample according to claim 1, wherein the FIB system is a dual-beam system provided with a FIB and an electron beam, and there is a 52-degree angle between the FIB and the electron beam.

11. The method for preparing a TEM sample according to claim 10, wherein the first protective layer is formed by means of an electron beam assisted deposition process.

12. The method for preparing a TEM sample according to claim 1, wherein the second protective layer is formed by means of an electron beam assisted deposition process.

13. The method for preparing a TEM sample according to claim 12, wherein the material of the second protective layer comprises carbon.

14. The method for preparing a TEM sample according to claim 10, wherein the sample stage has translation and rotation functions.

15. The method for preparing a TEM sample according to claim 1, wherein the FIB mark pattern is composed of a plurality of trench strips and comprises at least a first trench strip and a second trench strip parallel to each other, the first trench strip and the second trench strip respectively define two length edges of the TEM sample, and a distance between the first trench strip and the second trench strip defines the thickness of the TEM sample.
